(19) United States
(12) Patent Application Publication
(10) Pub. No.: US 2021/0194216 A1
(43) Pub. Date: Jun. 24, 2021

(54) STACKED SEMICONDUCTOR LASERS WITH CONTROLLED SPECTRAL EMISSION

(71) Applicant: Array Photonics, Inc., Tempe, AZ (US)

(72) Inventors: Aymeric MAROS, San Francisco, CA (US); Bed PANTHA, Chandler, AZ (US); Radek ROUCKA, East Palo Alto, CA (US); Sabeur SIALA, Sunnyvale, CA (US)

(21) Appl. No.: 17/131,292

(22) Filed: Dec. 22, 2020

Related U.S. Application Data
(60) Provisional application No. 62/953,253, filed on Dec. 24, 2019.

(51) Int. Cl. H01S 5/40; H01S 5/34; H01S 5/024; H01S 5/343; H01S 5/22

(52) U.S. Cl. CPC H01S 5/4043; H01S 5/3416; H01S 5/02469; H01S 5/2215; H01S 5/34306; H01S 5/3408; H01S 5/3407; H01S 5/34353

(57) ABSTRACT

Stacked edge-emitting lasers having multiple active regions coupled together using tunnel junctions. The composition of each of the active regions (quantum wells and/or barriers) differs to provide a controlled different emission wavelength for each junction, when each junction is individually operated at the same fixed temperature. When the device is under operation, a thermal gradient exists across the junctions, and the emission wavelengths of each junction coincide as the different temperature for each junction causes relative wavelength shifts. Thus, the effect of temperature on the emission wavelength of the device is compensated for, producing a narrower linewidth emission.

### CROSS-REFERENCE TO RELATED APPLICATION

This application claims the benefit of U.S. Provisional Application No. 62/953,253, filed Dec. 24, 2019, the contents of which is incorporated herein by reference in its entirety for all purposes.

### FIELD OF THE DISCLOSURE

The present invention relates to multiple junction semiconductor laser devices. More particularly, this disclosure relates to semiconductor lasers where the multiple junctions (referred to herein simply as junctions, for short) are structurally connected with what is known in related art as tunnel junctions (interchangeably referred to herein as tunnels, for short), and where effective bandgaps of the multiple junctions are chosen to be different from one another so as to produce, in operation of the laser devices, corresponding light emissions at different wavelengths from the junctions when all junctions operate at the same temperature. Once so configured, as a result of formation of a thermal gradient across the multi junction structure during the operation of the laser device, the temperature of each of the junctions changes, and the lasing wavelengths substantially coincide, thereby producing an overall narrow emission spectrum. Different waveguiding structures may also be used to ensure that the threshold currents for the various junctions also substantially match one another, so that all the constituent sub-lasers of the multi junction laser device operate simultaneously with substantially the same threshold current.

### BACKGROUND OF THE DISCLOSURE

Laser diodes having multiple beams and/or high power outputs have applications including diode-pumped solid-state lasers, range finding, LIDAR, and “friend-or-foe” identification. For many applications, it is preferable to use light at eye-safe wavelengths greater than about 1.2 μm. Laser structures or devices with multiple junctions electrically coupled together with the use of tunnel junctions (or tunnels) and capable of producing multiple beams, or those with beam combinations that allow for higher total power outputs to be achieved have been considered (see, for example, U.S. Pat. Nos. 5,212,706, 6,584,130, and 8,194,712). The optical field outputs produced by the stacked lasers may be spatially coupled together or decoupled as separate beams. This can be achieved by appropriately selecting the compositions and thicknesses of material layers that define the laser and waveguiding structures. Such laser structures may emit light at multiple wavelengths and they may also have different threshold currents for different constituent portions of the laser structures, which in turn can lead to non-linear light output as a function of the current density.

One reason for different spectral (wavelength) operation of the constituent individual lasers in a laser stack is the thermal conductivity of the semiconductor layers. In each individual laser junction, loss processes (such as non-radiative recombination, for example) result in a situation when not all injected current generates or causes light output. Instead, such losses cause generation of heat. The stacked laser junctions are formed on a common substrate that is mounted to a heatsink, or the devices may be “flipped” such that the heatsink is closer to the top-most junction in an epitaxially-grown structure. Consequently, individual junctions are separated from the heatsink by different distances (are different distances away from the heatsink). Understandably, the laser junction closest to the heatsink can dissipate its excess heat to the heatsink the quickest, in the shortest amount of time, while the laser junction furthest from the heatsink dissipates its excess heat the slowest (since the heat must flow through the entire laser structure to reach the heatsink). Consequently, the operating temperatures of the adjacent junctions can differ. If the laser junctions are substantially identical, in terms of layer compositions and thicknesses used, each constituent laser of the multi junction laser structure will operate at its own, different from others wavelength due to the temperature dependence of the bandgap of the semiconductor materials used to form the junctions. This effect can, therefore, broaden the spectral width of the output light from the overall structure, which can be disadvantageous in some applications. Furthermore, as described by Garcia et al., in Appl. Phys. Lett., 71 (26) pp 3752-3754, 1997, the threshold currents for each laser junction may differ. This may be caused by lateral current spreading, or additional losses associated with a given junction such as surface recombination losses and/or optical losses associated with highly doped layers such as contact layers and tunnel junction layers in close proximity to the laser active regions. Consequently, multiple threshold currents for the junctions can lead to non-linear light-current characteristics, which can also be undesirable.

### SUMMARY

Embodiments of the invention provide a multi junction edge emitting laser structure that includes first and second laser junctions, and a tunnel junction configured to couple the first and second laser junctions. Here, a first material composition of a first quantum well of the first laser junction and a second material composition of a second quantum well of the second laser junction are configured such as (when the laser structure is externally maintained at a chosen temperature) to form a thermal gradient across the first and second laser junctions due to a difference between the first and second material compositions. The formed thermal gradient is configured to cause a first wavelength and a second wavelength to substantially coincide (the first and second wavelengths are wavelengths of respective laser emissions produced, in operation of the laser structure, by the first and second laser junctions). In one implementation of the laser structure, a quantum well of a chosen laser junction from the first and second laser junctions has a chosen material composition that includes any of InGaAs, InGaAsN, InGaAsSb, InGaAsNSb and GaAsNSb, while a material composition of a quantum well of a laser junction that is adjacent to such chosen laser junction differs from the chosen material composition. In substantially any implementation, at least one of the first and second laser junctions may include a quantum-well structure that contains at least one of a) a quantum well that is substantially nitrogen-free and that has a material composition InₓGa₁₋ₓAs_{1-y}Sb_{y} (with 0≤x≤0.4 and 0≤y≤0.4 and x+y≤0.4) and b) a barrier that includes at least one of GaAs, GaAs_{1-y}N_{y} (with 0<y<0.1, and GaAs_{1-y}P_{y}, where 0<y≤0.35). In such a case, this quantum-well structure is characterized by an emission wavelength in a range from about 900 nm to about 1300 nm. In substantially any implementation, at least one of the first and second laser junctions may include an identified quantum-well structure that contains at least one of i) a quantum well that is characterized by an emission wavelength and that has a material composition InₓGa₁₋ₓN_{y}As_{1-y-z}Sb_{z} (with either (a) 0≤x≤0.45, 0<y≤0.1, 0≤z≤0.45 and x+z≤0.45, or (b) 0.1≤x≤0.45, 0<y≤0.1, 0≤z≤0.1 and x+z≤0.45) and ii) a barrier that includes at least one of GaAs, GaAs_{1-y}N_{y} (with 0<y<0.1, and GaAs_{1-y}P_{y}, where 0<y≤0.35). In this case, an emission wavelength of said identified quantum-well structure is in a range from about 1100 nm and about 1600 nm. Alternatively or in addition, and in substantially any implementation of the laser structure, at least one of a first In-composition level, a first Sb-composition level, and a first sum of the first In-composition level and the first Sb-composition level of a first active region of the laser structure may be lower than a corresponding at least one of a second In-composition level, a second Sb-composition level, and a second sum of the second In-composition level and the second Sb-composition level a second active region of said laser structure by a value defined between 0.1% and 1.2%. Here, the first active region is defined to be located farther away from the heatsink than the second active region.

Embodiments of the invention additionally provide a multi junction edge emitting laser structure that includes first and second laser junctions coupled by a tunnel junction and a lateral confinement region in each of said first and second laser junctions (with such lateral confinement region configured to minimize spatial spreading of current across the laser structure during operation thereof and to ensure that a first threshold current density and a second threshold current density are substantially matched). Here, the first threshold current density is a threshold current density of the first laser junction, and the second threshold current density is a threshold current density of the second laser junction.

### BRIEF DESCRIPTION OF THE DRAWINGS

The following Description is made in reference to the Drawings that are used for illustration of but examples of implementations of the idea of the invention, are generally not to scale, and are not intended to limit the scope of the present disclosure.

FIG. 1 shows a schematic of a multi junction edge emitting laser.

FIG. 2 shows a layer structure for a multi junction edge emitting laser.

FIG. 3 shows a layer structure for another multi junction edge emitting laser.

FIG. 4 is a band edge diagram for a single laser junction within a multi junction edge emitting laser.

FIG. 5 is a band edge diagram of the multi junction edge emitting laser shown in FIG. 1 and FIG. 3.

FIG. 6 is a cross section of a multi junction laser.

FIG. 7 is a cross section of another multi junction laser having lateral confinement layers.

### DETAILED DESCRIPTION

The following detailed description refers to the accompanying drawings that show, by way of illustration, specific details and examples of embodiments in which the invention may be practiced. Other embodiments may be utilized, and structural, logical, and electrical changes may be made without departing from the scope of the invention. Various embodiments discussed below are not necessarily mutually exclusive, and sometimes can be appropriately combined. The following detailed description is, therefore, not to be taken in a limiting sense, and the scope of the embodiments of the present invention is defined only by the appended claims, along with the full scope of equivalents to which such claims are entitled.

Notwithstanding that the numerical ranges and parameters used in the description are approximations, these numerical values in the specific examples are reported as precisely as possible. Any numerical value, however, inherently contains certain errors necessarily resulting from the standard variation found in their respective testing measurements.

In particular, any numerical range recited herein is intended to include all sub-ranges encompassed therein and are inclusive of the range limits. For example, a range of “1 to 10” is intended to include all sub-ranges between (and including) the recited minimum value of about 1 and the recited maximum value of about 10, that is, having a minimum value equal to or greater than about 1 and a maximum value of equal to or less than about 10.

Also, in this application, the use of “or” means “and/or” unless specifically stated otherwise, even though “and/or” may be explicitly used in certain instances.

The term “lattice-matched”, or similar terms, refer to semiconductor layers for which the in-plane lattice constants of the materials forming the adjoining layers materials (considered in their fully relaxed states) differ by less than 0.6% when the layers are present in thicknesses greater than 100 nm. Further, in devices such as lasers with multiple layers forming individual regions (such as mirrors, waveguides or cladding layers) that are substantially lattice-matched to each other means define the situation when all materials in the junctions, that are present in thicknesses greater than 100 nm and considered in their fully-relaxed stated, have in-plane lattice constants that differ by less than 0.6%. Alternatively, the term substantially lattice-matched or “pseudomorphically strained” may refer to the presence of strain within a layer (which may also be thinner than 100 nm), as would be understood from context of the discussion. As such, base material layers, of a given layered structure, can have strain from 0.1% to 6%, from 0.1% to 5%, from 0.1% to 4%, from 0.1 to 3%, from 0.1% to 2%, or from 0.1% to 1%; or can have strain less than 6%, less than 5%, less than 4%, less than 3%, less than 2%, or less than 1%. Layers made of different materials with a lattice parameter difference, such as a pseudomorphically strained layers, can be grown on top of other lattice matched or strained layers without generating misfit dislocations. The term “strain” generally refers to compressive strain and/or to tensile strain.

While the discussion presented below addresses the embodiments of devices formed on a GaAs substrate (or on a substrate that has a lattice constant approximately equal to that for GaAs), the implementation of the idea of invention is not restricted to materials grown on GaAs substrates, but can be applied in principle to devices grown on other semiconductor substrates, including InP and GaSb.

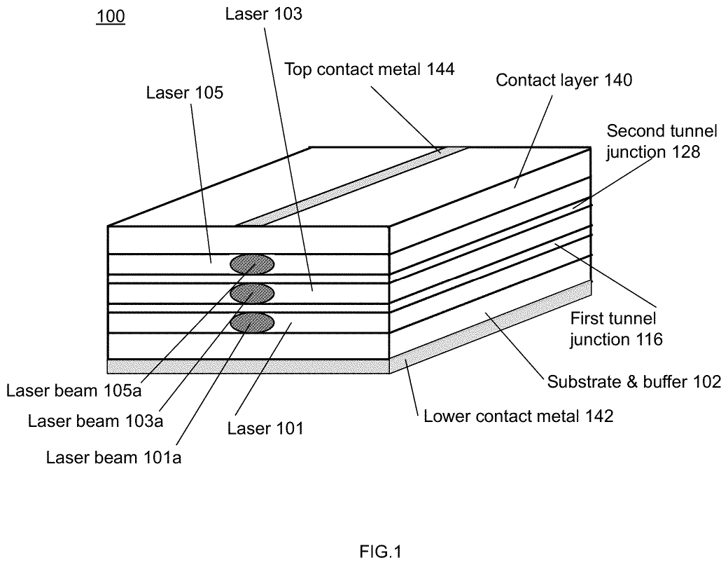

FIG. 1 is a schematic of a multi junction laser device 100. In practice, the layers of the device are deposited epitaxially on a substrate using a semiconductor growth technique such as molecular beam epitaxy (MBE) or metal-organic chemical vapor deposition (MOCVD), or metal-organic chemical vapor deposition (MOVPE) or organometallic vapor phase epitaxy (OMVPE). Hybrid growth, using a combination of both MBE and MOCVD epitaxy to form the device is also possible. The device 100 is shown as having three vertically stacked individual or constituent lasers that are electrically coupled together using tunnel junctions. According to the idea of the invention, a multi junction laser device such as the device 100, for example, has at least two laser junctions and one tunnel junction. As shown, the device 100 includes a substrate 102, a first laser structure or constituent laser 101, a first tunnel junction 116, a second laser structure or constituent laser 103, a second tunnel junction 128, a third laser structure or constituent laser 105, and a semiconductor contact layer 140. The device 100 also includes a top contact metal member 144 and a bottom contact metal member 142. In one case, the device 100 may be mounted to a heatsink (not shown).

Lateral confinement of current (not shown) may be achieved using standard semiconductor processing techniques. For a stripe laser, this may be achieved, for example, using ion or proton implantation to define high resistivity material regions on either side of the contact metal stripe 144. A buried heterostructure may be created through the process of etching material and subsequent semiconductor regrowth, to define a region through which current flows. Etching and oxidation steps may also be used, as will be described later.

Each laser structure 101, 103 and 105 in the device 100 is configured to provide, in operation, a corresponding output optical beam (beams 101a, 103a, and 105a, respectively). The optical fields of each of these beams of the stacked lasers 101, 103, 105 may be spatially coupled together or decoupled as separate beams. This can be achieved by appropriately selecting the compositions and/or thicknesses of material layers that define the laser and waveguiding structures. Optical beams 101a, 103a and 105a may also be coupled together using external optical components, including lenses, reflectors and/or phase masks.

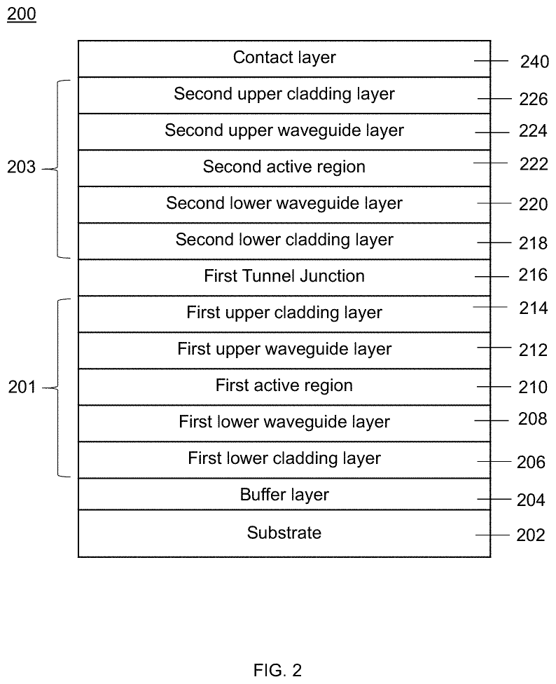

FIG. 2 shows a cross-section of a device 200, providing a more detailed illustration for a semiconductor layer structure of a device with two constituent lasers and one tunnel junction connecting these lasers. As shown, the device 200 includes a substrate 202, a buffer layer 204, a first laser structure (or laser) 201, a first tunnel junction 216, a second laser structure (or laser) 203, and a semiconductor contact layer 140. The first laser structure 201 includes a first lower cladding layer 206, a first lower waveguide layer 208, a first active region 210, a first upper waveguide layer 212 and a first upper cladding layer 214. The second laser structure 203 includes a second lower cladding layer 218, a second lower waveguide layer 220, a second active region 222, a second upper waveguide layer 224, and a second upper cladding layer 226. The laser structures 201 and 203 will be described in more detail later. Each laser structure forms a corresponding pn-junction.

In one case, the substrate 202 can be configured to have a lattice constant that matches or nearly matches the lattice constant of GaAs or Ge. The substrate can be made of GaAs, for example. The substrate 202 may be doped p-type, or n-type, or may be chosen to be a semi-insulating (SI substrate). The thickness of the substrate 202 can be chosen to be any suitable thickness, typically between about 150 μm and 750 μm. The thickness of the substrate may be reduced (that is the substrate may be thinned) after epitaxial growth to a value of about 50 μm to about 150 Substrate 202 may be configured to include one or more sub-layers, for example, substrate 202 can include epitaxially grown material (such as a ternary or quaternary semiconductor), or be a buffered or composite substrate. In a related case, the substrate 202 can include a Si layer having an overlying SiGeSn buffer layer (which is engineered to have a lattice constant that matches or nearly matches the lattice constant of GaAs or Ge). In this specific case, the substrate 202 can have a lattice parameter different from that of GaAs or Ge by a value that is less than or equal to 3%, preferably less than 1%, or even more preferably less than 0.5%. In substantially any implementation, the lattice constant of the substrate 202 is judiciously chosen to minimize defects in materials subsequently grown thereon.

The device 200 is shown to include a buffer layer 204 overlying (or carried by) and adjacent to the substrate 202. In general, and unless explicitly stated otherwise, as broadly used and described in this application, the reference to a layer or element as being “carried” on a surface of an element or another layer refers to both a layer that is disposed directly on the surface of the element/layer or a layer that is disposed on yet another coating, layer or layers that are disposed directly on the surface of the element/layer. The buffer layer 204 has a lattice constant that matches or nearly matches the lattice constant of the substrate 202. The buffer layer 204 may have the same material doping as that of the substrate, and may be doped p-type, or n-type, or may be semi-insulating. In some embodiments grown on a semi-insulating substrate, the buffer layer 204 may also be doped p-type or n-type dopants in order to facilitate electrical connection in subsequent device processing steps after the overall structure has been grown. The thickness of the buffer layer 204 may be between about 0 and 2 μm. In cases where a GaAs or a Ge substrate 202 is used, the buffer layer 204 can include GaAs, AlGaAs, InGaP, or InAlP.

A first laser structure 201 overlies (or is carried by) the substrate 202 and buffer 204. The laser structure 201 includes a first lower cladding layer 206 and a first upper cladding layer 214 that sandwich a first lower waveguide layer 208; a first active region 210; and a first upper waveguide layer 212. The bandgap of material(s) that form the cladding layers 206 and 214 is chosen to be higher than that of material(s) employed for waveguiding layers 208 and 212. The refractive index(es) of waveguiding layers 208 and 212 is/are chosen to be higher than the refractive index(es) of the cladding layers 206 and 210. Consequently, the optical spatial mode generated by the laser structure can be substantially confined to the active region and waveguiding layers. In one implementation, the cladding and waveguiding layers can include AlₓGa₁₋ₓAs, where 0≤x≤1 or AlₓGa₁₋ₓAs_{1-y}P_{y}, where 0≤x≤1 and 0<y≤0.15. The cladding and waveguiding layers may have compositions that differ from each other to produce a desired refractive index and bandgap profile across the structure 200. Using AlₓGa₁₋ₓAs layers as an example, the waveguiding layers may be less Aluminum than the cladding layers. For example, the waveguiding layers 208 and 212 may be made of GaAs, while the cladding layers 206 and 214 may be made of Al_{0.33}Ga_{0.67}As. The thicknesses of cladding layers 206 and 214, independently, may each be between about 0.5 μm and about 2 μm, and those of the waveguiding layers 208 and 212, independently, may each be between about 100 nm and about 2 μm, or between about 100 nm and about 1 μm, or between about 100 nm and about 0.5 μm, or between about 100 nm and about 250 nm, depending on the specific implementation. In one case, the first lower cladding layer 206 is doped with a dopant of a first type (such as n-type or p-type) with a doping concentration level between about 1×10¹⁷ cm⁻³ and 8×10¹⁸ cm⁻³, or between about 5×10¹⁷ cm⁻³ and 5×10¹⁸ cm⁻³ as an alternative, while the first upper cladding layer 2012 is doped with a dopant of the type that is opposite to the first type (such as p-type or n-type, respectively, in this example) with a doping concentration level between about 1×10¹⁷ cm⁻³ and 8×10¹⁸ cm⁻³, or between about 5×10¹⁷ cm⁻³ and 5×10¹⁸ cm⁻³ as an alternative. Examples of p-type dopants include Be and C. Examples of n-type dopants include Si, Te, and Se.

In a specific case, the first lower cladding layer 206 and the first upper cladding layer 214 may have different thicknesses, and/or compositions, and/or doping concentration levels. The first lower cladding layer 206 and the first upper cladding layer 214 may, independently, include sub-layers with different doping levels, and/or compositions and/or thicknesses. The first lower waveguiding layer 208 and the first upper waveguiding layer 212 are, on the other hand, typically undoped. However, in some embodiments at least a portion of the waveguiding layers 208 and 212 may be doped at a doping level lower than about 1×10¹⁷ cm⁻³, in order to reduce series resistance while, at the same time, minimizing waveguide optical losses associated with the presence of the dopant material. The first lower waveguiding layer 208 and first upper waveguiding layer 212, independently, may also have different thicknesses and material compositions, thereby forming an asymmetric waveguide. In some embodiments, a thickness for one of the lower or upper waveguide layers may be about 1 μm and the thickness for the other waveguiding layer may be about 1.5 μm. In other embodiments, the thinner waveguide layer may have a thickness between about 100 nm and 1 μm, and the thicker waveguide layer may have a thickness between about 1 μm and 2 μm. In some embodiments, one of the lower or upper waveguides may have a composition AlₓGa₁₋ₓAs while the other waveguide may have a composition of Al_{y}Ga_{1-y}As, where 0≤x≤1 and 0≤y≤1, and x and y are not of the same value, or where 0.1≤x≤0.6 and 0.1≤y≤0.6, and x and y are not of the same value, such as Al_{0.3}Ga_{0.7}As and Al_{0.2}Ga_{0.8}As for example. Such a waveguide can be useful in controlling the spot size of the output beam of a laser, as well as reducing internal losses, both of which are useful for high power laser operation. Alternatively, or in addition, the first lower waveguiding layer 208 and first upper waveguiding layer 212 may, independently, include sub-layers with different compositions, and/or doping levels, and/or thicknesses. In a specific case, the first lower waveguiding layer 208 and first upper waveguiding layer 212 may, independently, include layers with substantially continuously graded compositions, where the bandgap monotonically increases away from the active region 210 towards the cladding layer.

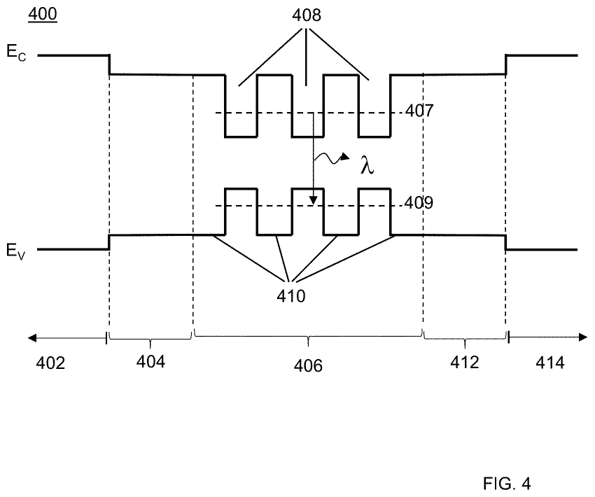

The active region 210 overlies and is adjacent to the first lower waveguiding layer 208 and, at the same time, underlies and is adjacent to the first upper waveguiding layer 212. The active region 210 includes at least one quantum well, formed using a first semiconductor material layer formed between two barrier layers (here, such first semiconductor material layer has a first composition, a first thickness, and a first bandgap while the two barrier layers are made of another semiconductor material having a second composition, a second thickness and a second bandgap, where the second bandgap is larger than the first bandgap). As will be explained in further detail (with respect to FIG. 4), the bandgap of the barrier layers is judiciously chosen to be larger than the bandgap of the quantum well layers in order to provide electrical confinement for both injected electrons and injected holes into the quantum wells. The quantum wells and barriers define an effective bandgap for the active region, which determines the emission wavelength from the laser structure. Material compositions for the quantum wells may include InGaAs, InGaAsSb, InGaAsN, GaInNAsSb, and GaNAsSb, and the quantum well thicknesses can be between about 5 nm and 12 nm. Depending on a particular implementation, material compositions for the barrier layers may include any of AlGaAs, GaAs, GaAsN, GaAsP, GaAsN(Sb) and the barrier thickness can be between about 5 nm and 30 nm. Effective bandgaps for the active region can lie between about 0.77 eV and 1.4 eV, corresponding to emission wavelengths between about 900 nm and about 1600 nm.

As shown schematically in FIG. 2, the tunnel junction 216 overlies and is adjacent to the first laser structure 201. In one example, the tunnel junction 216 includes a thin highly doped n+ layer and a thin highly doped p+ layer adjacent to each other. The n+ layer is adjacent to an n-doped cladding layer of one laser structure (of the structures 201 and 203) and the p+ layer is adjacent to a p-doped cladding layer of another laser structure (of the structures 201 and 203) in the device 200. The tunnel junction 216 is configured to electrically connect the laser structure 201 with the laser structure 203 in the device 200. When the device 200 is operated under forward bias, a hole-based current flow in the “p” region from one laser structure is converted into an electron-based current flow in the “n” region of another laser structure. As a result, a highly conductive, virtually metallic contact junction is established between the vertically neighboring laser structures 201 and 203. It is required for this purpose that the doping concentrations in the layers of the n+p+ tunnel junction lie in the range of between about 10¹⁹ cm⁻³ and about 10²⁰ cm⁻³. An example of a tunnel junction is provided by a GaAs/AlGaAs tunnel junction, in which each of the GaAs and AlGaAs layers forming such tunnel junction has a thickness between 5 nm and 100 nm. An n-doped GaAs layer can be doped with Te, Se, S and/or Si, and a p-doped AlGaAs layer can be doped with C or Be. In some tunnel junctions, GaAs may be used instead of AlGaAs. In some tunnel junctions, AlGaAs may also be used instead of GaAs. In some tunnel junctions, InGaAs or GaAsSb may also be used instead of GaAs and/or AlGaAs.

As shown, the second laser structure 203 overlies (is carried by) and is adjacent to the first tunnel junction 216. Here, the second laser structure 203 is similar to the laser structure 201, and has a second lower cladding layer 218, a second lower waveguide layer 220, a second active region 222, a second upper waveguide layer 224, and a second upper cladding layer 226. Any of the compositions, and/or thicknesses, and/or doping levels used in the layers (218, 220, 222, 224 and 226) of the laser structure 203 can differ from those used in the first laser structure 201 (layers 206, 208, 210, 212 & 214). The compositions and thicknesses can be chosen such that in operation, each laser emits light at the same wavelength, and each laser operates with the same threshold current.

The contact layer 240 overlies and is adjacent to (carried by) the second laser structure 203. In one embodiment, the contact layer 240 includes a highly doped layer on which a metallic contact layer (not shown in FIG. 2) can be formed. For example, material of the contact layer 240 includes GaAs and has a thickness between about 20 nm and about 250 nm, and a doping concentration level between about 10¹⁹ cm⁻³ and about 10²⁰ cm⁻³.

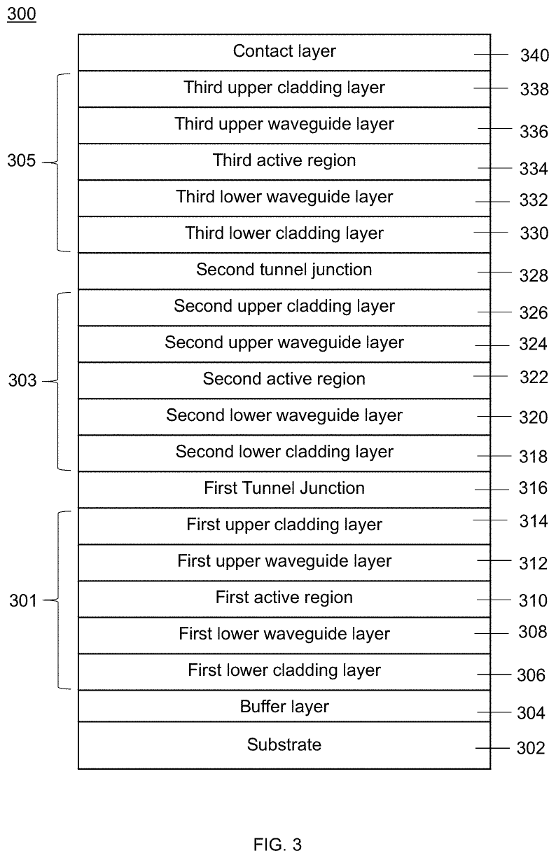

FIG. 3 presents a related embodiment and shows an alternative layer structure 300 configured as the device 100 of FIG. 1. The structure 300 is similar to structure 200 of FIG. 2, but incorporates three constituent laser structures instead of two. From the comparison of FIGS. 3 and 2 it can be appreciated that here a second tunnel junction 328 is formed or added over the base two-laser structure (represented by layers 202-226 in FIG. 2, or layers 302-326 in FIG. 3). The material compositions, and/or thicknesses, and/or and doping concentration levels for second tunnel junction 328 may be similar to those for the first tunnel junction (represented by the layer 316 in FIG. 3 or a layer 216 in FIG. 2). A third constituent laser structure 305 is then formed over the second tunnel junction 328. This third laser structure 305 is similar to laser structures 301 and 303 (or 201 and 203 of the embodiment of FIG. 2), and has a third lower cladding layer 330, a third lower waveguide layer 332, a third active region 334, a third upper waveguide layer 336, and a second upper cladding layer 338. The overall epitaxial structure of the device 300 is then complemented with the doped semiconductor contact layer 340. While in one implementations the laser structures 301, 303, 305 may be similar or even substantially identical, these laser structures must be carefully designed to ensure that in operation, each of these constituent lasers within the overall laser device 300 emits light at the same wavelength, and each of these lasers also operates with the same threshold current.

Generally, all material layers of embodiments 100, 200 and 300 can be—and preferably are—either lattice matched or pseudomorphically strained to the substrate.

FIG. 4 illustrates the band edge alignment of a single laser structure 400 used to form a constituent laser component within an overall device configured according to an embodiment 100, 200 or 300. On this diagram, the conduction band edge is denoted Ec and the valence band edge is denoted Ev. The illustrated band edge alignment could be used, for example, in a constituent laser (sub)-structure 301, 303 or 305, with the relative band edge positions determined by different material compositions of the layers. The laser structure 400 includes cladding layers 402 and 414 and waveguide layers 404 and 412. In one implementation, the material compositions, and/or thicknesses, and/or and doping concentration levels of these cladding and waveguide layers can be chosen to be substantially the same as those described above with respect to the embodiment 200 and/or embodiment 300. In one case, the bandgap of the material of the cladding layers is chosen to be larger than the bandgap of the material of the waveguiding layers.

The active region 406 is structured to include a quantum-well structure with quantum wells 408 and barrier layers 410. The quantum wells 408 and barrier layers 410 have no intentionally-introduced doping and are, therefore, undoped or nominally undoped or have a very low background doping level below 1×10¹⁶ cm⁻³. Generally, the active region 406 includes at least one quantum well 408 adjacent to at least two barrier layers 410. In this specific example, as shown, the active region 406 of the embodiment 400 includes three quantum wells 408 and four barrier layers 410, and more generally—in a related embodiment—the active region 406 may be configured to include n quantum wells and n+1 barrier layers, where n is an integer greater than or equal to one. The quantum well(s) 408 have a thickness T_{QW} and a composition C_{QW}, and the barrier layers have a thickness T_{B} and a composition C_{B}. The quantum well structure 406 defines an energy level for confined electrons 407, and an energy level for confined holes 409. The energy separation of these levels (or “effective bandgap”) corresponds to a peak emission wavelength for the quantum well structure. Depending on the specific implementation, the quantum well(s) 408 can be dimensioned to have thicknesses between about 5 nm and about 12 nm. Quantum well(s) 406 can include nitrogen-free materials such as InGaAs, InGaAsSb, and/or GaAsSb, and dilute nitride materials such as InGaAsN, GaInNAsSb, GaNAsSb, GaInNAsBi, and/or GaInNAsSbBi that are either lattice matched or pseudomorphically strained to the substrate. Similarly, in related embodiments the barrier layers 410 can be dimensioned to have thicknesses between about 5 nm and about 30 nm, and can include any of AlGaAs, GaAs, GaAsN, GaAsP, and GaAsN(Sb), that are either lattice-matched or pseudomorphically strained to the substrate. The barrier layers 410 may have more than one sub-layer, with differing material compositions. In one example, the quantum wells may be characterized by compressive strain, while the barrier layers may possess tensile strain to provide a strain-compensated active region that allows for an additional quantum wells to be formed in order to increase the optical gain of the overall embodiment, in operation. The value of the effective bandgap of the active region can be between about 0.77 eV and about 1.4 eV, which corresponds to emission wavelengths in the range from about 900 nm to about 1600 nm.

In at least one case, the quantum wells are structured to be nitrogen-free and have a composition InₓGa₁₋ₓAs_{1-y}Sb_{y}, where 0≤x≤0.4 and 0≤y≤0.4 and x+y≤0.4, while the barriers are configured to include GaAs, GaAs_{1-y}N_{y}, where 0<y≤0.1 and/or GaAs_{1-y}P_{y}, where 0<y≤0.35. The corresponding emission wavelength for the quantum well structures may be between about 900 nm and about 1300 nm. Non-limiting examples of dilute nitride semiconductor quantum well structures are described in U.S. Pat. Nos. 6,798,809 and 7,645,626, the disclosure of each of which is incorporated herein by reference. When the dilute nitride quantum wells are employed, these wells may have a material composition InₓGa₁₋ₓN_{y}As_{1-y-z}Sb_{z}, where 0≤x≤0.45, 0<y≤0.1, 0≤z≤0.45 and x+z≤0.45, or where 0.1≤x≤0.45, 0<y≤0.1, 0≤z≤0.1 and x+z≤0.45, while the barriers may include GaAs, GaAs_{1-y}N_{y}, where 0<y≤0.1 or where 0<y≤0.03 and/or GaAs_{1-y}P_{y}, where 0<y≤0.35. The emission wavelength for such quantum well structures may extend from about 1100 nm up to about 1600 nm.

In some cases, where the embodiments 100, 200 and 300 are chosen to include at least two constituent laser structures or junctions, such embodiments may be formed on a common substrate that is mounted to a heatsink. In other cases, the corresponding layered structures may be “flipped” such that the heatsink is disposed closer to the top-most laser junction in an epitaxially-grown structure. Consequently, each constituent laser junction within a given embodiment is located at a respectively-corresponding distance away from the heatsink, and these separation distances are different for different constituent laser junctions of a given embodiment. Understandably, the laser junction located closer to the heatsink can dissipate its excess heat to the heatsink quicker than the laser junction located father from the heatsink, since the heat must flow through the entire laser structure to reach the heatsink. (In this case, the heat dissipation process associated with the farthest-from-the heatsink junction is the slowest, while the heat dissipation process associated with the closest-to-the-heatsink junction is the quickest.) Consequently, the operating temperatures of the spatially-adjacent constituent laser junctions of the same embodiment of the overall laser structure can differ, with the junction temperature increasing the farther away from the heatsink this junction is. It is known that a band gap of a semiconductor material decreases with increasing temperature. As a result, the distance (on the energy-spectrum scale) between the quantized energy levels in the quantum well layers also decreases, thereby increasing the emission wavelength. Therefore, if different constituent laser junctions of the same overall laser structure are otherwise identical in terms of layer compositions and thicknesses used, the corresponding constituent lasers of such multi junctions laser structure can be expected to operate at different wavelengths due to the temperature dependence of the bandgap of the semiconductor materials used to form the corresponding junctions.

According to the idea of the invention—and to overcome or compensate this “differing wavelengths of operation” effect—the compositions and/or thicknesses of the quantum wells and barrier layer in each adjacent laser structure (e.g., laser junctions 201 and 203 of the embodiment 200 of FIG. 2) are appropriately changed to make the difference between the wavelengths of light emission from the different constituent laser junctions smaller (and even substantially negligible or nonexistent, in one specific case). In this case, when the semiconductor layer structure and the heatsinking conditions for different constituent laser junctions are different, these premeditated material differences will define such different temperature regimes of operation for different laser junctions of the embodiment that determine substantially similar or equal wavelengths of operation. For example, during the operation of the structure 200 the laser junction 201 will be at temperature T₁ while the laser junction 203 will be at temperature T₂ (with the difference between T₁ and T₂ determined by the difference between the semiconductor layer structure and heatsinking conditions of these two junctions), with the resulting relative shift of the wavelengths such that the emission wavelengths of these two different laser junctions substantially coincide.

In reference to FIG. 4, one laser junction can be configured to have quantum wells with composition C_{QW1} and thickness T_{QW1}, and barrier layers with composition C_{B1} and thickness T_{B1}. Another laser junction can be configured to have quantum wells with composition C_{QW2} and thickness T_{QW2}, and barrier layers with composition C_{B2} and thickness T_{B2}. At least one composition or thickness differs between the two laser junctions.

The difference in the quantum well structure (required to ensure that the difference between the wavelengths of operation of the different junctions is minimized or even zeroed) depends on the thermal impedance characteristics of the devices. The thermal behavior of the stacked laser structure (such as structures 100, 200, 300) may be modeled using a simple heat diffusion model or, as a person of skill will readily appreciate, it may be calculated using an empirical model based on device measurements for laser devices mounted to different heatsinks. Examples of thermal models for lasers are described by Szymanski et al., in “Mathematical Models of Heat Flow in Edge-Emitting Semiconductor Lasers”, Heat Transfer—Engineering Applications, Vyacheslav S. Vikhrenko, IntechOpen, DOI: 10.5772/26527, available from www.intechopen.com/books/heat-transfer-engineering-applications/mathematical-models-of-heat-flow-in-edge-emitting-semiconductor-lasers, the contents of which are incorporated herein by reference in their entirety. This allows an estimate of the operating temperature of each junction, and hence the wavelength shift that is required between adjacent laser junctions within the device. The required composition change, or layer thickness change can then be determined.

Typical values of thermal impedances for edge emitting lasers, available from related art, can be shown to lead to a temperature difference between adjacent laser junctions of the multi junction laser structure of about 5 K to up to 20 K, or between about 10 K and 15 K in one case. When the multi junction laser structure is configured to utilize InGaAs QWs and dilute nitride QWs, the lasing wavelength shift as a function of temperature can be determined to be between about 0.24 nm/K and about 0.36 nm/K. The resulting wavelength shift between wavelengths of emission of light from adjacent laser junctions can therefore lie between about 1.2 nm and about 7.2 nm, or between about 2.4 nm and 5.4 nm in a related case.

For quantum well structures, a 1% change in In composition may produce an approximately 7.5 nm to 8.5 nm shift in the wavelength, while a 1% change in Sb composition may produce a wavelength shift between about 6 nm and 7.5 nm. A decrease in the In and/or Sb composition increases the electron-hole energy separation, decreasing the emission wavelength. Thus, in order to produce the desired bandgap change (and associated wavelength shift) between adjacent active regions of the multi junction (stacked) laser structure, the compositional change (specifically, decrease) required in the quantum well for In, Sb, or a combination of In and Sb may be in a range between about 0.1% and about 1.2%, or between about 0.15% and about 1% in a related embodiment, or between about 0.25% and about 0.9% in yet another embodiment. In one example, the InₓGa₁₋ₓN_{y}As_{1-y-z}Sb_{z} quantum wells in a first active region that is closest to a heatsink may have an In-composition of about 35% (x=0.35), while a second active region located farther from the heatsink may have quantum wells with an In-composition of, for example, 34% (x=0.34), and a third active region still farther from the heatsink may have quantum wells with an even lower In— composition (for the purposes of illustration—of 33% (x=0.33)). In another example, InₓGa₁₋ₓN_{y}As_{1-y-z}Sb_{z} quantum wells in a first active region may be characterized with x=0.33 and z=0.01, where x+z=0.34 (34%), and the quantum wells in a second active region may be characterized with x=0.325 and z=0.05, where x+z=0.33 (33%). Therefore, a decrease in the In and/or Sb composition of the quantum wells of a laser junction corresponding to increase of a separation distance between such junction and the heatsink can be used to compensate for the effect of temperature-caused variation of emission wavelength during the device operation. Alternatively or in addition, changes in nitrogen composition may also be used, with compositional changes smaller than about 0.1% (for example, between 1.2% and 1.3%) or smaller than about 0.2% in a related embodiment.

As a quantum well decreases in thickness, the energy level separation increases and the corresponding operational wavelength decreases. Thus, the quantum well thickness between adjacent active regions may also be changed to affect the resulting wavelength of operation. Depending on a particular implementation of the idea of the invention, decreases in quantum well width (between adjacent active regions of the multi junction laser structure) of less than about 1 nm or less than about 0.5 nm or less than about 0.2 nm may be used, with the thinner quantum wells of the multi junction laser structure being disposed or formed farther from the heatsink. For example, quantum wells in a first active region may have a thickness of 7.5 nm and quantum wells in a second active region may have a thickness of 7.4 nm, or quantum wells in a first active region may have a thickness of 7.4 nm and quantum wells in a second active region may have a thickness of 7.2 nm, and quantum wells in a third active region may have a thickness of 7 nm.

In some examples, the barrier thickness and/or composition may also be judiciously changed to achieve the same goal of bringing the operational wavelengths of different constituent laser junctions of the same multi junction laser structure closer together. In some embodiments, decreases or increases in barrier width may be less than about 5 nm, or less than about 2 nm or less than about 1 nm. For GaAs and GaAs_{1-y}N_{y} barrier layers, for example, the change in nitrogen composition of the barrier layer may be less than about 0.1% (for example, between 1.2% and 1.3%), or less than about 0.2%, or less than about 0.5%, or less than about 1%. Inclusion of nitrogen in the barrier layer changes the band offsets of the barrier layer with respect to the well, but also decreases the lattice constant, producing a material with tensile strain. This provides additional strain compensation of the compressively strained QWs, thereby also affecting the effective bandgap of the QW structure.

Another problem recognized in operation of a laser device with stacked (multiple) laser junctions is caused by the fact that the current required to reach a threshold value can differ for each constituent laser. Consequently, this can result in non-linear light-current characteristics. The threshold current values can differ for different junctions due to several reasons. Firstly, lateral current spreading can affect injected current density at the different junctions, and, as a result, the threshold current density may not be reached in each and every constituent laser of the overall multi junction laser system under a given operating current—thus lasing might not occur in all junctions at the same time. There may also be additional losses associated with a given junction (such as surface recombination losses and/or optical losses related to highly doped layers such as contact layers and tunnel junction layers located in close proximity to the laser active regions). These shortcomings may be compensated for “vertically” (using different waveguide designs for each constituent laser sub-structure within the overall device) and/or “laterally” (through the use of appropriate confinement structures). The waveguide design for each junction can be adjusted, for example, to judiciously change the overlap between the optical field and the active region for each laser sub-structure, thereby changing the effective gain between the different laser sub-structures. This result can be achieved using different compositions and/or thicknesses for the waveguide layers and cladding layers for each of the junctions, providing a different refractive index profile and hence optical mode profile for each of the laser structures. (Such approach can be used, for example, to decrease the gain of a laser structure that has the lowest threshold current in order to match it to the threshold current of another laser structure within the device.)

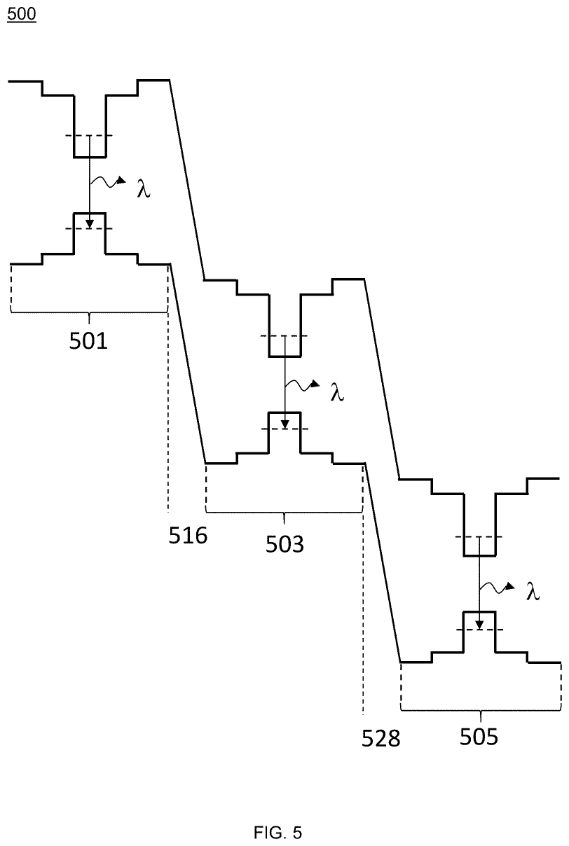

In reference to FIG. 5, an example of an energy band structure 500 of the multiple-junction semiconductor laser structure of FIG. 1 (configured according to the embodiment 300 of FIG. 3) is shown schematically. A skilled artisan will readily appreciate that depicted are the bands 501, 503 and 505 (corresponding to three laser junctions 301, 303, 305) and connected with the band portions 516, 528 (corresponding to tunnel junctions 316 and 328). The presence of the tunnel junctions in the laser structure allows for serial electrical connection of the neighboring laser junctions and associated electron-hole conversion. The laser junction closest to the heatsink can dissipate heat produced the quickest and has the lowest effective bandgap. The junction farthest from the heatsink can dissipate heat produced slower, comparatively speaking, and has a higher operating temperature during operation of the overall device. Consequently, such junction has the highest effective bandgap. This compensates for the lowering of the energy levels brought about by the temperature influence, so that the active zones of the three semiconductor lasers emit light with the same wavelength.

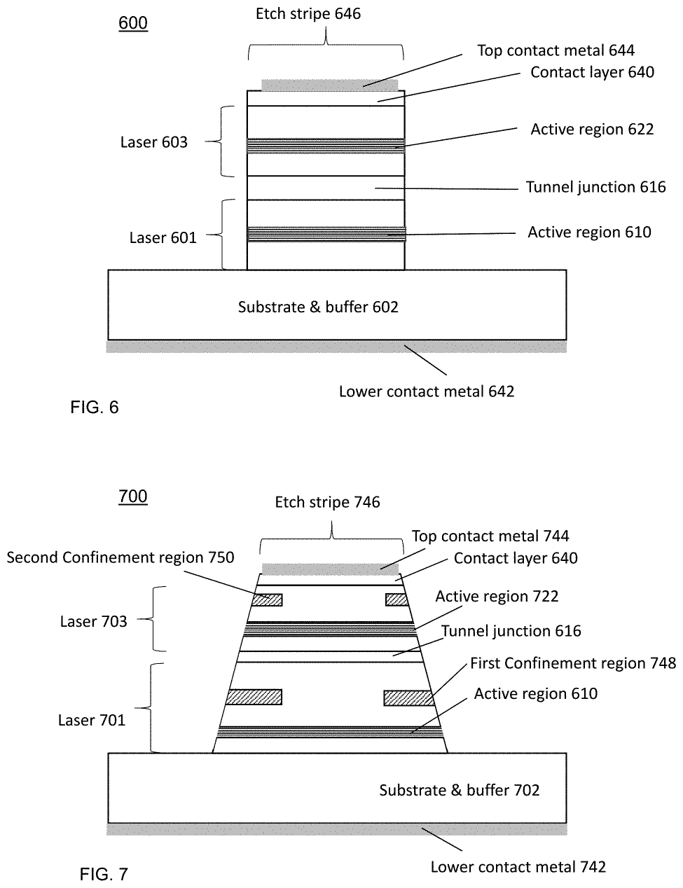

FIG. 6 shows a cross-section of a stacked multi junction laser device 600 with an etched stripe. The etch stripe has a width 646. The embodiment 600 includes a substrate and buffer 602, a bottom laser structure 601 with an active region 610, a tunnel junction 616, a top laser structure 603 with an active region 622, a contact layer 640, a lower contact metal layer 642, and upper contact metal layer 644. The device 600 may include other auxiliary layers (not shown) such as, for example, a passivation layer to reduce surface losses associated with the etched sidewalls. Passivation layers are known and may include dielectric materials such as silicon oxide, silicon nitride and Al₂O₃. In the device as shown, the threshold currents for the two constituent laser structures 601, 603 could be expected to be substantially equal, as there is no spatial current spreading. However, during the etching process to form the ridge or stripe 646, the sidewalls of the upper laser structure 603 are necessarily exposed to the etching environment for a time longer than the time of exposure to the same environment of the laser structure 601. This may increase the rate of surface recombination at the junction of the upper laser 603 compared to the junctions of the lower laser 601, thereby resulting in a higher threshold current for the upper laser 601. By reducing the waveguiding effect on the junction of the lower laser 601, its threshold current can be appropriately increased to match the threshold current of the top laser junction 603.

FIG. 7 provides another example of a laser device 700 with an etched ridge or stripe 346, where there is a variation of the stripe width as a function of depth (or height of the stripe). The etch stripe 746 has a smaller width at the top and can be broader at the base of the etched stripe. The difference in geometrical parameters of the stripe 746 as a function of its height can lead to current spreading, which process reduces the current density for laser junctions located at spatially-lower levels of the device 700. Design of waveguiding structure may not be able to completely compensate for this effect, hence the additional use of lateral confinement structures can be employed to control the active width and volume of the current injection region in each of the present laser junctions. The laser device embodiment 700 includes a substrate and buffer 702, a bottom laser structure 701 with an active region 710, a tunnel junction 716, a top or upper laser structure 703 with an active region 722, a contact layer 740, a lower metal 742, and an upper or top metal contact layer 744. The device 700 also includes a first current confinement region 748 for a constituent laser structure 701 (defining a first width of a region associated with the current injection) and a second confinement region 750 for a constituent laser structure 703 (defining a second width of a region associated with the current injection). Device 700 may include other, auxiliary layers (not shown) such as a passivation layer, for example, to reduce surface losses associated with the etched sidewalls of the ridge 746, and to protect surfaces of layers during an oxidation process step, to prevent oxidation of layers other than the layers to be oxidized to form the confinement layers. Passivation layers are known to include, for example, dielectric materials such as silicon oxide, silicon nitride and Al₂O₃. First and second confinement regions 748 and 750 can be formed in a cladding layer for each of the laser junctions with the use of ion or proton implantation and/or selective oxidation. The process of ion implantation produces a highly resistive region, while defining the low resistivity region through which current can flow. In the embodiment 700, two different implant depths may be required and so ion implantation may need to take place at two different energy levels.

The oxide confinement process produces a highly resistive region by selective oxidation of a high aluminum-content layers using known methods. For devices formed on GaAs substrate, the layer or layers for oxidation typically include Al_{y}Ga_{1-y}As, where y is greater than 0.9. The oxidation process forms confinement region that has (a) a low refractive index and (b) high resistivity, when compared to the unoxidized region of material, and therefore provides both optical and electrical confinement. Since the width of the etch stripe varies as a function of depth, different oxidation lengths are required for each confinement region in order to produce the desired current confinement. The oxidation rate for an oxidation layer is dependent on the composition of the layer and the thickness of the layer. Thus, the thickness and/or composition for confinement regions 748 and 750 may need to be different in order to provide the same current confinement effect for each laser junction.

Additionally, for at least one of the laser junctions (and, in one case, for each laser junction), an Al_{y}Ga_{1-y}As oxidation layer can be grown as a part of the cladding layer for such junction, where y>0.9 or y>0.97. The thickness of the oxidation layer, if so formed, can be between about 10 nm and about 70 nm. Notably, the oxidation rate for a layer with a higher Al content is higher than for a layer with lower Al content. The oxidation rate also increases with increasing layer thickness. Therefore, based on the knowledge or assessment of the etch stripe geometry and the desired oxidation length for the oxidation layer for a given laser junction, the composition and/or thickness of the corresponding confinement layer can be chosen so as to produce different oxidation lengths in a single-step oxidation process (with the process controlling the confining width to be the same for more than one junction). This operation can result in matching the current density between junctions to within 1%, or at least within 2%, or at least within 5% depending on the details of a particular implementation. In the case of the embodiment 700, the oxidation length required for the laser junction 701 is greater than the oxidation length required for the laser junction 703. Therefore, the confinement region 748 can have a higher Al content than the confinement region 750, while having the same thickness as that of the confinement region 750. Alternatively, and in related embodiment, the confinement region 748 can also be thicker than the confinement region 750, while having the same material composition as that of the confinement region 750. In yet another related embodiment, a combination of different compositions and thicknesses for these confinement layers may also be used.

Standard oxidation process calibration procedures can be used to determine the oxidation rates for AlGaAs materials, and therefore to determine the composition and thickness of the oxidation layer(s) required for a given etch process. For a device with a uniform etch stripe width, the confinement region composition and/or thickness may also differ to compensate for differing threshold conditions for the different laser junctions of the device, thereby ensuring the threshold carrier concentration required for each of the multiple junction is achieved for the same (substantially equal for every junction) current injection level.

The inclusion of oxide confinement layers within the embodiment 700 may affect thermal conductivity characteristics of this device, increasing the temperature gradient across the laser junctions 701 and 703. Such increase of the temperature gradient may be compensated for with appropriate adjustments to the active regions 710 and 722, as previously described.

To fabricate embodiments of semiconductor optoelectronic devices structured according to the idea of the invention, a plurality of layers can be deposited on an appropriate substrate in a first-materials-deposition chamber. Such plurality of layers may include etch-stop layers; release layers (i.e., layers designed to release the semiconductor layers from the substrate when a specific process sequence, such as chemical etching, is applied); contact layers such as lateral conduction layers; buffer layers; layers forming reflectors or mirror structures, and/or or other semiconductor layers. For example, the sequence of layers deposited on the substrate in the first-materials-deposition chamber can include buffer layer(s), then a lateral conduction or contact layer(s). Next, the substrate can be transferred to a second-materials-deposition chamber, where a waveguide region or confinement region and an active region are formed on top of the existing, already-deposited semiconductor layers. The substrate may then be transferred to either the first-materials-deposition chamber or to a third-materials-deposition chamber for deposition of additional layer(s) such as contact layers. Tunnel junctions may also be formed, in some implementations.

The movement or repositioning/relocation of the substrate and semiconductor layers from one deposition chamber to another chamber is referred to as transfer. The transfer may be carried out in vacuum, at atmospheric pressure in air or another gaseous environment, or in an environment having mixed characteristics. The transfer may further be organized between materials deposition chambers in one location, which may or may not be interconnected in some way, or may involve transporting the substrate and semiconductor layers between different locations, which is known as transport. Transport may be done with the substrate and semiconductor layers sealed under vacuum, surrounded by nitrogen or another gas, or surrounded by air. Additional semiconductor, insulating or other layers may be used as surface protection during transfer or transport, and removed after transfer or transport before further deposition.

For example, a dilute nitride active region and waveguiding region can be deposited in a first-materials-deposition chamber, while the AlGaAs/GaAs cladding and other structural layers can be deposited in a second-materials-deposition chamber. To fabricate edge emitting devices discussed in this disclosure, some or all of the layers of the active region, including a dilute nitride based active region can be deposited with the use of molecular beam epitaxy (MBE) on one deposition chamber, and the remaining layers of the laser can be deposited with the use of chemical vapor deposition (CVD) in another materials deposition chamber.

In some embodiments, a surfactant, such as Sb or Bi, may be used when depositing any of the layers of the device. A small fraction of the surfactant may also incorporate within a layer.

A semiconductor device comprising a dilute nitride layer can be subjected to one or more thermal annealing treatments after growth. For example, a thermal annealing treatment includes the application of a temperature in a range from about 400° C. to about 1,000° C. for a duration between about 10 microseconds and about 10 hours. Thermal annealing may be performed in an atmosphere that includes air, nitrogen, arsenic, arsine, phosphorus, phosphine, hydrogen, forming gas, oxygen, helium, or any combination of the preceding materials.

The invention as recited in claims appended to this disclosure is intended to be assessed in light of the disclosure as a whole, including features disclosed in prior art to which reference is made.

For the purposes of this disclosure and the appended claims, the use of the terms “substantially”, “approximately”, “about” and similar terms in reference to a descriptor of a value, element, property or characteristic at hand is intended to emphasize that the value, element, property, or characteristic referred to, while not necessarily being exactly as stated, would nevertheless be considered, for practical purposes, as stated by a person of skill in the art. These terms, as applied to a specified characteristic or quality descriptor means “mostly”, “mainly”, “considerably”, “by and large”, “essentially”, “to great or significant extent”, “largely but not necessarily wholly the same” such as to reasonably denote language of approximation and describe the specified characteristic or descriptor so that its scope would be understood by a person of ordinary skill in the art. In one specific case, the terms “approximately”, “substantially”, and “about”, when used in reference to a numerical value, represent a range of plus or minus 20% with respect to the specified value, more preferably plus or minus 10%, even more preferably plus or minus 5%, most preferably plus or minus 2% with respect to the specified value. As a non-limiting example, two values being “substantially equal” to one another implies that the difference between the two values may be within the range of +/−20% of the value itself, preferably within the +/−10% range of the value itself, more preferably within the range of +/−5% of the value itself, and even more preferably within the range of +/−2% or less of the value itself. The term “substantially equivalent” may be used in the same fashion. In a specific example, when two wavelengths are stated to substantially coincide, the substantial coincidence is defined as and implies that the wavelengths at hand do not differ from one another by more than 5 nm, preferably by not more than 2 nm, even more preferably by not more than 1 nm.

The use of these terms in describing a chosen characteristic or concept neither implies nor provides any basis for indefiniteness and for adding a numerical limitation to the specified characteristic or descriptor. As understood by a skilled artisan, the practical deviation of the exact value or characteristic of such value, element, or property from that stated falls and may vary within a numerical range defined by an experimental measurement error that is typical when using a measurement method accepted in the art for such purposes.

Although specific embodiments have been illustrated and described herein, it will be appreciated by those of ordinary skill in the art that any arrangement that is calculated to achieve the same purpose may be substituted for the specific embodiments shown. This application is intended to cover any adaptations or variations of embodiments of the present invention. It is to be understood that the above description is intended to be illustrative, and not restrictive, and that the phraseology or terminology employed herein is for the purpose of description and not of limitation. Combinations of the above embodiments and other embodiments will be apparent to those of skill in the art upon studying the above description. The scope of the present invention includes any other applications in which embodiment of the above structures and fabrication methods are used. The scope of the embodiments of the present invention should be determined with reference to claims associated with these embodiments, along with the full scope of equivalents to which such claims are entitled.

1. A multi junction edge emitting laser structure comprising:
a first laser junction having a first wavelength;
a second laser junction having a second wavelength; and
a tunnel junction coupling the first laser junction and the second laser junction,
wherein a first material composition of a first quantum well of the first laser junction and a second material composition of a second quantum well of the second laser junction differ such that a thermal gradient is formed across the first laser junction and the second laser junction when the laser structure is externally maintained at a temperature,
wherein the thermal gradient causes the first wavelength and the second wavelength to substantially coincide.

2. The multi junction edge emitting laser structure of claim 1,
wherein at least one of: the first laser junction and the second laser junction includes a quantum-well structure that includes at least one of:
a) a quantum well that is substantially nitrogen-free and has a material composition of InₓGa₁₋ₓAs_{1-y}Sb_{y}, wherein 0≤x≤0.4 and 0≤y≤0.4 and x+y≤0.4, and
b) a barrier that includes at least one of GaAs, GaAs_{1-y}N_{y}, wherein 0<y<0.1, and GaAs_{1-y}P_{y}, wherein 0<y≤0.35;
wherein the quantum-well structure has an emission wavelength in a range from about 900 nm to about 1300 nm.

3. The multi junction edge emitting laser structure of claim 1,
wherein at least one of: the first laser junction and the second laser junction includes a quantum-well structure that includes at least one of:
i) a quantum well having a material composition of InₓGa₁₋ₓN_{y}As_{1-y-z}Sb_{z}, wherein either (a) 0≤x≤0.45, 0<y≤0.1, 0≤z≤0.45 and x+z≤0.45, or (b) 0.1≤x≤0.45, 0<y≤0.1, 0≤z≤0.1 and x+z≤0.45, and
ii) a barrier that includes at least one of GaAs, GaAs_{1-y}N_{y} wherein 0<y<0.1, and GaAs_{1-y}P_{y} wherein 0<y≤0.35;
wherein the quantum-well structure has an emission wavelength in a range from about 1100 nm and about 1600 nm.

4. The multi junction edge emitting laser structure of claim 1, wherein:
the first laser junction includes a first active region having a first composition level, the first composition level being at least one of: a first In-composition level, a first Sb-composition level, and a first sum of the first In-composition level and the first Sb-composition level,
the second laser junction includes a second active region having a second composition level, the second composition level being at least one of: a second In-composition level, a second Sb-composition level, and a second sum of the second In-composition level and the second Sb-composition level, and
the first composition level is between 0.1% and 1.2% lower than the second composition level.

5. The multi junction edge emitting laser structure of claim 4, further comprising:
a heatsink, wherein the first active region is located farther away from the heatsink than the second active region.

6. The multi junction edge emitting laser structure of claim 4, wherein the first composition level is between 0.25% and 0.9% lower than the second composition level.

7. The multi junction edge emitting laser structure of claim 1, wherein:
the first laser junction includes a first active region having a first nitrogen composition level,
the second laser junction includes a second active region having a second nitrogen composition level, and
the first nitrogen composition level is less than 0.2% lower than the second composition nitrogen level.

8. The multi junction edge emitting laser structure of claim 1, wherein:
the first quantum well has a first width,
the second quantum well has a second width, and
the first width is 1 nm or less than the second width.

9. The multi junction edge emitting laser structure of claim 8, further comprising:
a heatsink, wherein the first quantum well is located farther away from the heatsink than the second quantum well.

10. The multi junction edge emitting laser structure of claim 1, further comprising:
a third laser junction having a third wavelength;
a second tunnel junction coupling the second laser junction and the third laser junction,
wherein a third material composition of a third quantum well of the third laser junction and the second material composition differ such that a second thermal gradient is formed across the second laser junction and the third laser junction when the laser structure is externally maintained at the temperature,
wherein the second thermal gradient causes the second wavelength and the third wavelength to substantially coincide.

11. The multi junction edge emitting laser structure of claim 10, wherein:
the first material composition and the third material composition are different, and
the first wavelength and third wavelength substantially coincide when the laser structure is externally maintained at the temperature.

12. The multi junction edge emitting laser structure of claim 10, wherein:
the first laser junction includes a first active region having a first composition level, the first composition level being at least one of: a first In-composition level, a first Sb-composition level, and a first sum of the first In-composition level and the first Sb-composition level,
the second laser junction includes a second active region having a second composition level, the second composition level being at least one of: a second In-composition level, a second Sb-composition level, and a second sum of the second In-composition level and the second Sb-composition level,
the third laser junction includes a third active region having a third composition level, the third composition level being at least one of: a third In-composition level, a third Sb-composition level, and a third sum of the third In-composition level and the third Sb-composition level,
the first composition level is between 0.1% and 1.2% lower than the second composition level, and
the second composition level is between 0.1% and 1.2% lower than the third composition level.

13. The multi junction edge emitting laser structure of claim 10, wherein:
the first laser junction includes a first active region having a first nitrogen composition level,
the second laser junction includes a second active region having a second nitrogen composition level,
the third laser junction includes a third active region having a third nitrogen composition level,
the first nitrogen composition level is less than 0.2% lower than the second composition nitrogen level, and
the second nitrogen composition level is less than 0.2% lower than the third composition nitrogen level.

14. The multi junction edge emitting laser structure of claim 10, wherein:
the first quantum well has a first width,
the second quantum well has a second width,
the third quantum well has a third width,
the first width is 1 nm or less than the second width, and
the second width is 1 nm or less than the third width.

15. A multi junction edge emitting laser structure comprising:
a first laser junction having a first threshold current density and including a first lateral confinement region;
a second laser junction having a second threshold current density and including a second lateral confinement region; and
a tunnel junction coupling the first laser junction to the second laser junction;
wherein the first threshold current density and the second threshold current density are substantially matched.

16. The multi junction edge emitting laser structure of claim 15, wherein:
the first lateral confinement region has a first width,
the second lateral confinement region has a second width, and
the first width is different from the second width.

17. The multi junction edge emitting laser structure of claim 15, wherein:
the first lateral confinement region has a first thickness and a first composition,
the second lateral confinement region has a second thickness and a second composition, and
at least one or more of: the first thickness is different from the second thickness, and the first composition is different from the second composition.

18. The multi junction edge emitting laser structure of claim 15, wherein at least one of: the first lateral confinement region and the second lateral confinement region is an oxidized Al_{y}Ga_{1-y}As layer, where y>0.9.

19. The multi junction edge emitting laser structure of claim 18, wherein:
the first lateral confinement region has a first oxidation length,
the second lateral confinement region has a second oxidation length, and
the first oxidation length is greater than the second oxidation length.

20. The multi junction edge emitting laser structure of claim 15, wherein a thermal gradient is formed across the first laser junction and the second laser junction when the laser structure is externally maintained at a temperature.
